(19) United States
(12) Patent Application Publication
(10) Pub. No.: US 2002/0163026 A1
(43) Pub. Date: Nov. 7, 2002

(54) Capacitor and method of manufacturing the same

(76) Inventor: Hong-Bae Park, Seoul (KR)

Correspondence Address: HARNESS, DICKEY & PIERCE, P.L.C., P.O. BOX 8910, RESTON, VA, 20195, US

(21) Appl. No.: 10/131,475

(22) Filed: Apr. 25, 2002

(30) Foreign Application Priority Data
May 2, 2001 (KR) 2001-23773

(51) Int. Cl. H01L 27/108; H01L 29/76; H01L 29/94; H01L 31/119

(52) U.S. Cl. 257/301

(57) ABSTRACT

A capacitor in which a generation of a bad storage node can be reduced and a method of manufacturing the same. An opening is formed at a portion of an insulating layer on a semiconductor substrate for exposing a conductive structure under the insulating layer. A polysilicon film is formed on a top surface of the insulating layer and a sidewall and a bottom surface of the opening. A supporting film is formed on the polysilicon film. The polysilicon film and the supporting film are partially etched so that the polysilicon film and the supporting film remain only on the sidewall and the bottom surface of the opening, thereby forming a storage electrode. A dielectric film and a plate electrode are formed on the storage electrode. The generation of a bad capacitor can be reduced by using the supporting film to keep the node of the storage electrode from being inclined.

### BACKGROUND OF THE INVENTION

1. Field of the Invention

The present invention relates to a capacitor and a method of manufacturing the same, and more particularly, the present invention relates to a capacitor for a semiconductor device and a method of manufacturing the same.

2. Description of the Related Art

Recently, semiconductor devices have been developing rapidly as their use in computers and computer-related devices increases. To be useful in such applications, semiconductor devices should operate at high speed and have sufficient storage capacitance. In order to satisfy these requirements, the trend in fabricating semiconductor devices has been to improve the degree of integration, reliability and response speed.

A DRAM device is an example of a device widely used as a semiconductor device, which has a large capacitance and in which data is easily input and output. The typical DRAM device has a memory cell region in which data is stored and a peripheral circuit region through which the data is input and output. The typical DRAM device includes an access transistor and a storage capacitor.

The storage capacitor usually has small physical dimensions to permit increased integration. It is important to fabricate a storage capacitor of small size and sufficient storage capacitance. One goal of storage capacitor design is to increase the storage capacitance of the capacitor, while not increasing the area occupied by the storage capacitor on the substrate.

In order to increase the storage capacitance of the capacitor, a method of increasing an “effective area” of the capacitor, while not increasing the area occupied by the storage capacitor on the substrate, has been developed. According to this method, a structure of the capacitor is modified from a flat structure to a stacked structure or a trench-type structure. In a capacitor having a stacked structure, a cylindrical capacitor or a fin-type capacitor has been developed to increase the effective area of the capacitor.

FIGS. 1A to 1D are sectional views of illustrating a conventional method of forming a cylindrical capacitor.

Referring to FIG. 1A, a first insulating layer 12 is formed on a semiconductor substrate 10. The first insulating layer 12 has a contact plug 14 to make contact with a portion of the semiconductor substrate 10. An etching stop layer 16 is coated on the first insulating layer 12, on which a second insulating layer 18 is formed.

Referring to FIG. 1B, a portion of the second insulating layer 18 is etched to form an opening 18a, in which a part of the first insulating layer 12 and an upper portion of the contact plug 14 are exposed.

Referring to FIG. 1C, a polysilicon film is deposited on a sidewall and a bottom surface of the opening 18a to form a storage electrode 20.

In order to form the storage electrode 20, the polysilicon film is deposited to a uniform thickness on the second insulating layer 18 and the sidewall and the bottom surface of the opening 18a. Then, a sacrificial layer is used to fill up the opening 18a in which the polysilicon film is coated on the sidewall and the bottom surface, of which an upper portion is etched back to form the storage electrode 20 and an associated node unit.

Referring to FIG. 1D, a dielectric film 22 and a plate electrode 24 are formed on the storage electrode 20 so as to complete the capacitor.

However, at least one deficiency with this process is that bridges are frequently created between nodes of the storage electrode 20 when the capacitor is formed on the semiconductor substrate 10. Bridges are especially common when the capacitor is formed in accordance with current minute design rules, where a height of the storage electrode 20 becomes higher and a distance between the nodes becomes shorter. Under such a design rule, the nodes of the storage electrode 20 are inclined or fall down to make contact with an adjacent node during a subsequent process, resulting in a bit failure on a pair of the unit cells.

FIG. 2A is a sectional view and FIG. 2B is a plan view of a capacitor in which a failure is generated due to the inclination of the storage nodes.

Referring to FIG. 2A, when the storage nodes are inclined, the bridges occur between the adjacent storage nodes (see A in FIG. 2A) or the spaced distance between the storage nodes becomes narrow (see B in FIG. 2A).

Referring to FIG. 2B, each top portion of the cylindrical storage electrodes 20 has a circle shape in the plan view. As shown in FIG. 2B, the top portions of the storage electrodes 20 make contact with one another (see A in FIG. 2B) or the spaced distance between the top portions of the storage electrodes 20 becomes narrow (see B in FIG. 2B).

If bridges occur between the storage nodes, the two unit cells including the two storage electrodes in which the bridge occurs, cause a pair bit or function failure.

The pair bit or function failure of the unit cells due to the inclination of the storage nodes, may be generated throughout a wafer as well as being continuously generated between the two cells. Therefore, since the number of the function failure cells increase, it is difficult to repair the function failure cells. Furthermore, since the function failure cells occur in a post-process of fabricating the semiconductor device, the productivity of the semiconductor device is decreased and the fabricating cost is increased.

Japanese Laid-Open Patent Publication No. Heisei 11-297960 to Nakamura et al. discloses a method of preventing a process error such as an inclination of storage nodes.

According to the Nakamura et al., an oxide film or a nitride film is formed at a certain height between the adjacent storage nodes. Accordingly, such film can prevent the storage nodes from being inclined. However, when using the Nakamura et al. method, an effective area of the storage electrode is reduced to the extent of the height of the film. Furthermore, the height of a film for supporting the storage electrode also must increases if the height of the storage electrode increases. Accordingly, it is difficult to form a capacitor having a sufficient capacitance.

### SUMMARY OF THE INVENTION

The present invention is directed to one or more embodiments of a capacitor and one or more embodiments of making the same, in which the generation of a function or pair bit failure is reduced in a storage electrode.

In at least one exemplary embodiment, the present invention is directed to a capacitor comprising a storage electrode of a polysilicon film which is continuously coated on a side wall and a bottom surface of an opening which partially exposes a conductive structure formed under the storage electrode, the opening being formed at a portion of an insulating layer formed on a semiconductor substrate and the insulating layer being removed after forming the storage electrode, a supporting film pattern, formed on an inner surface and a bottom surface of the storage electrode, for supporting the storage electrode, and a dielectric film and a plate electrode, which are subsequently formed on the storage electrode on which the supporting film pattern is formed.

In at least one other exemplary embodiment, the present invention is directed to a capacitor comprising a storage electrode of a polysilicon film, a supporting film pattern, formed on an inner surface and a bottom surface of the storage electrode, for thermally supporting the storage electrode, and a dielectric film and a plate electrode, which are subsequently formed on the storage electrode on which the supporting film pattern is formed.

In at least one other exemplary embodiment, the present invention is directed to a capacitor comprising a storage electrode of a polysilicon film, a supporting film pattern, formed on an inner surface and a bottom surface of the storage electrode, for supporting the storage electrode, and a dielectric film and a plate electrode, which are subsequently formed on the storage electrode on which the supporting film pattern is formed.

In at least one other exemplary embodiment, the present invention is directed to a method of manufacturing a capacitor comprising:

forming an opening at a portion of an insulating layer which is formed on a semiconductor substrate for exposing a conductive structure under the insulating layer;

forming a polysilicon film on the insulating layer, a side wall and a bottom surface of the opening;

forming a supporting film for supporting the polysilicon film on the polysilicon film;

forming a storage electrode of the polysilicon film on the side wall and the bottom surface of the opening by partially removing the polysilicon film and the supporting film which are formed on the insulating layer; and

forming a dielectric layer and a plate electrode on the storage electrode.

In at least one other exemplary embodiment, the present invention is directed to a method of manufacturing a capacitor comprising:

forming an opening at a portion of an insulating layer which is formed on a semiconductor substrate for exposing a conductive structure under the insulating layer;

forming a polysilicon film on the insulating layer, a side wall and a bottom surface of the opening;

forming a supporting film for thermally supporting the polysilicon film on the polysilicon film;

forming a storage electrode of the polysilicon film on the side wall and the bottom surface of the opening by partially removing the polysilicon film and the supporting film which are formed on the insulating layer; and

forming a dielectric layer and a plate electrode on the storage electrode.

As described above, by forming the supporting film on the polysilicon film, each node of the storage electrode is less likely to be inclined by a subsequent process. Accordingly, at least one advantage is that pair bit failures can be reduced.

### BRIEF DESCRIPTION OF THE DRAWINGS

The above and other objects and advantages of the present invention will become readily apparent by reference to the following detailed description when considered in conjunction with the accompanying drawings wherein:

FIGS. 1A to 1D are sectional views of illustrating a conventional method of forming a cylinder type of capacitor;

FIG. 2A is a sectional view of showing a failure of a capacitor when a storage node is inclined;

FIG. 2B is a plan view of showing the failure of the capacitor when the storage node is inclined;

FIG. 3 is a sectional view of a semiconductor device having a cylinder type of capacitor according to at least one embodiment of the present invention; and

FIGS. 4A to 4G are sectional views of illustrating a method of forming a capacitor in the semiconductor device according to at least one embodiment of the present invention.

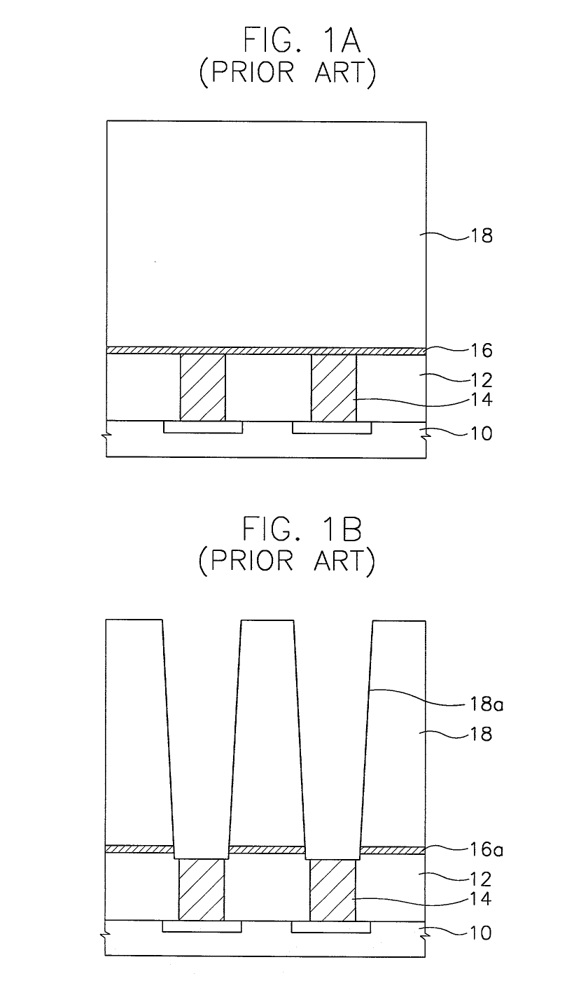

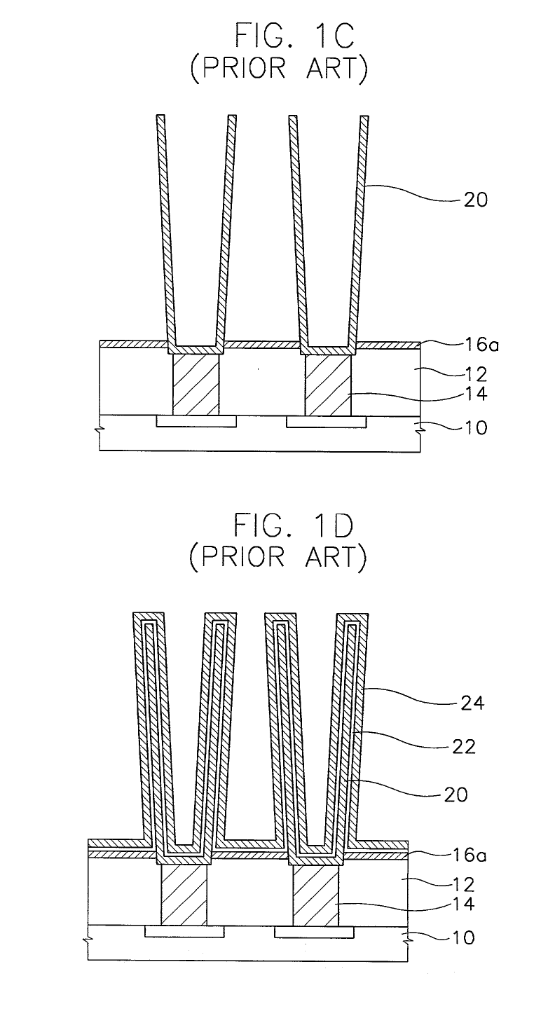

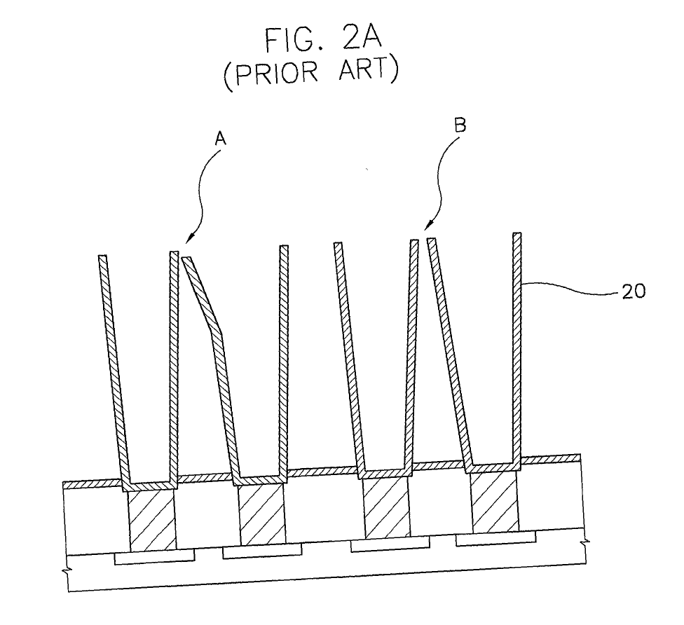

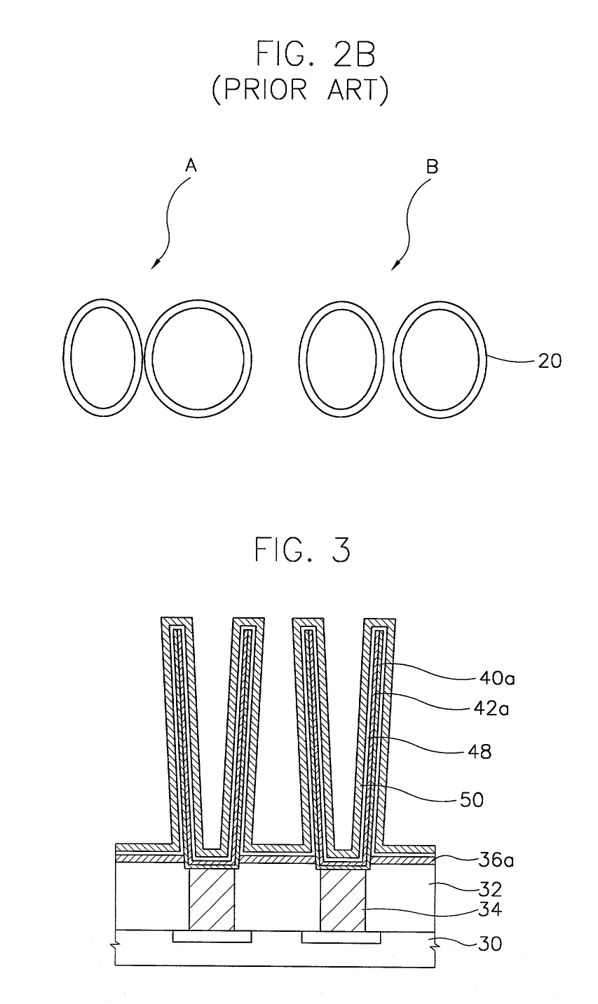

### DETAILED DESCRIPTION OF THE PREFERRED EMBODIMENT

Hereinafter, the various embodiments of the present invention will be described in detail with reference to the accompanying drawings.

FIG. 3 is a sectional view of showing a semiconductor device having a cylindrical capacitor according to at least one embodiment of the present invention.

Referring to FIG. 3, a cylindrical storage electrode 40a is formed on an insulating layer 32 and makes contact with a conductive structure 34 formed under the cylindrical storage electrode 40a which is formed on a semiconductor substrate 30.

In particular, the conductive structure 34, for example, a contact plug connected to a contact region of the capacitor node, for example, a source region of a transistor are prepared on an active region of the semiconductor substrate 30. The cylindrical storage electrode 40a makes electrical contact with a top surface of the conductive structure 34. The storage electrode 40a may have a height of about 10,000 to 17,000 Å.

A supporting film pattern 42a is formed on an inner surface and a bottom surface of the storage electrode 40a. The supporting film pattern 42a has a thickness of about 10 to 30 Å. Further, the supporting film pattern 42a is comprised of silicon oxynitride (SiON) or silicon nitride (SixNy).

A dielectric film 48 and a plate electrode 50 are formed on the storage electrode 40a on which the supporting film pattern 42a is formed.

In the capacitor having a structure as described above, therefore, as the storage node is supported by the supporting film pattern 42a formed on the inner surface and the bottom surface of the storage electrode, the storage node is less likely to be inclined.

Hereinafter, a method of manufacturing the capacitor according to at least one embodiment of the present invention will be described in detail with reference to the accompanying drawings.

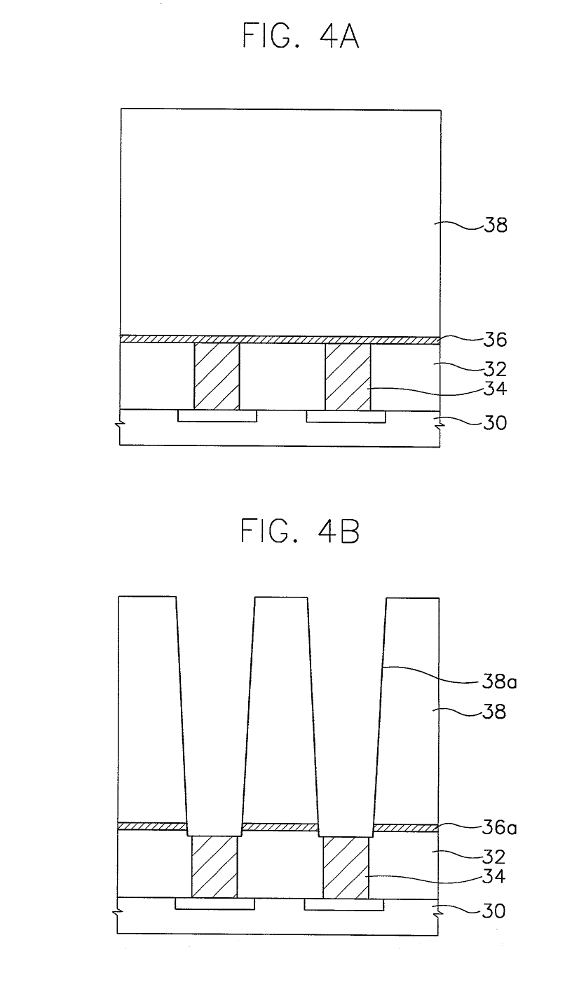

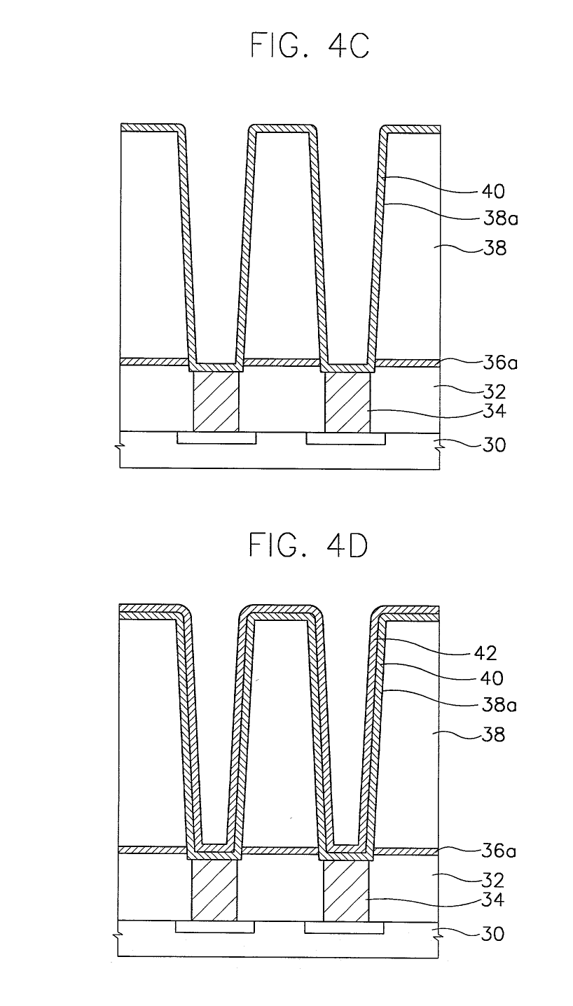

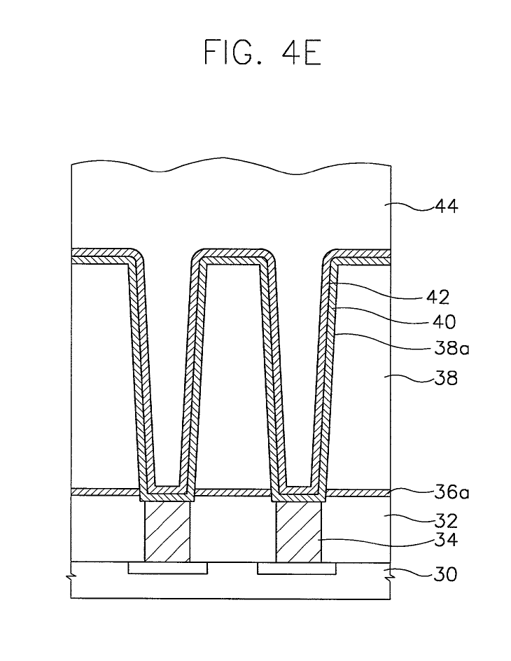

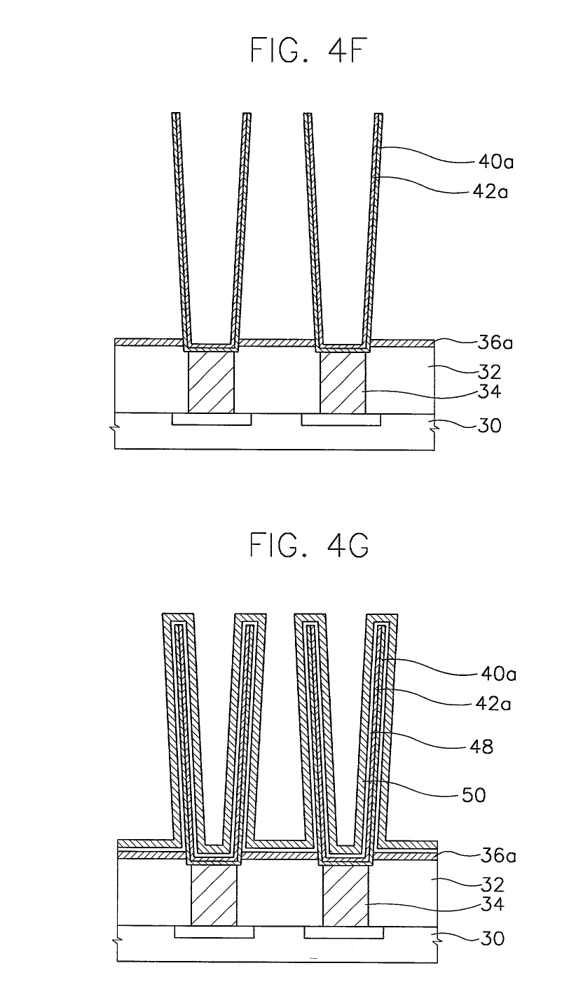

FIGS. 4A to 4G are sectional views of illustrating the method of manufacturing the capacitor of the semiconductor device according to at least one embodiment of the present invention. A DRAM cell will be described as an example of the semiconductor device.

FIG. 4A shows a step of forming the conductive structure at a location of the first insulating layer 32 formed on the semiconductor substrate 30. The conductive structure 34 may be a contact plug which makes electrical contact with the contact region of the capacitor node of the semiconductor substrate 30. Further, an etching stop layer 36 may be formed on the first insulating layer 32 including the contact plug.

At least one technique for forming the conductive structure 34 will be described below in detail.

A field region and an active region on which elements are formed, may be defined on the semiconductor substrate 30 by a conventional isolation process. An element structure (not shown) including the contact region of the capacitor node is formed in the active region. The element structure may include a MOS transistor, a bite line or other similar structure. In the method of forming the element structure, after a thin gate oxide film is grown on the active region of the semiconductor substrate, a polysilicon layer doped with impurities and a tungsten silicide layer are stacked on the gate oxide film to form a gate electrode having a polycide structure. Then, by using the gate electrode as a mask, impurities are implanted into the active region to form source/drain regions of the transistor.

An insulating interlayer is formed on the semiconductor substrate 30 on which the transistor is formed and then a portion of the insulating layer is etched to form a bite line contact hole. The polysilicon is deposited on the insulating interlayer to fill up the bite line contact hole, on which the tungsten silicide layer is deposited. Then, thus obtained layers are patterned via a photolithography process to form a bite line having a polycide structure. The bite line makes contact with the source region or the drain region of the transistor.

The first insulating layer 32 is formed on the semiconductor substrate 30 having an element structure (not shown). An oxide film is deposited on the insulating interlayer to form the first insulating layer 32. Hereinafter, the first insulating layer 32 is used to denote an insulating layer including the insulating interlayer. The portion of the first insulating layer 32 is etched in order to form the contact hole which exposes the source region of the semiconductor substrate 30. The conductive material fills up the contact hole. Then, the top portion of the conductive material is etched back to form the conductive structure 34 such as the contact plug in the first insulating layer 32.

An etching stop layer 36 is formed on the first insulating layer 32 including the conductive structure 34. A material such as silicon nitride or silicon oxynitride, which has a high selectivity ratio with respect to the first insulating layer 32 (that is, which shows a high etching resistance when compared to the first insulating layer 32 in a predetermined etching process), is deposited to a thickness of about 100˜1000 Å on the first insulating layer so as to form the etching stop layer 36.

FIG. 4B shows the step of forming the opening 38a which exposes the top surface of the conductive structure 34 and a portion of the first insulating layer 32 adjacent to the conductive structure 34 after a second insulating layer 38 is formed on the etching stop layer 36.

Since the storage node electrode is formed on the sidewall and the bottom surface of the opening 38a via a subsequent process, the second insulating layer 38 should be formed to have a height higher than that of the storage electrode.

The second insulating layer 38 is formed to have a height of about 15,000˜18,000 Å. A photoresist pattern is formed on the second insulating layer 38 for exposing the top surface of the conductive structure 34, and then the second insulating layer 38 is etched by using the photoresist pattern as an etching mask. Accordingly, the opening 38a is formed to have a depth of about 15,000˜18,000 Å.

The second insulating layer 38 is etched to the depth where the etching stop layer 36, which is formed on the first insulating layer 32 and the conductive structure 34, is exposed. Particularly, after the second insulating layer 38 is etched until the etching stop layer 36 is exposed, the second insulating layer 38 is excessively etched to form the opening 38a which exposes the top surface of the conductive structure 34 and a portion of the first insulating layer 32.

The opening 38a has a lower portion narrower than an upper portion thereof. Therefore, a sidewall of the opening 38a is inclined at an angle because the etching rate decreases at the lower portion of the opening 38a by a loading effect during the etching process.

FIG. 4C shows the step of forming a polysilicon film 40 on the sidewall and the bottom surface of the opening 38a and the top surface of the second insulating layer 38.

After removing the photoresist pattern used as the etching mask, the polysilicon film is deposited to a substantially uniform or uniform thickness along a profile of the opening 38a. As the polysilicon film 40 has a good deposition characteristic, the polysilicon film 40 does not fill up the opening 38a but is deposited to the substantially uniform or uniform thickness on the sidewall and the bottom surface of the opening 38a and the top surface of the second insulating layer 38. The polysilicon film 40 has the thickness of about 200˜1,000 Å.

FIG. 4D shows the step of forming a supporting film 42 for supporting the polysilicon film 40. The supporting film 42 is formed to a thickness of about 5˜30 Å, which is comprised of silicon nitride (SixNy) or silicon oxynitride (SiON).

In particular, the supporting film 42 may be formed via a rapid thermal nitridation process in which the ambient gas including the nitrogen source is supplied to the semiconductor substrate 30 to nitride the surface of the polysilicon film 40. After the silane gas and ammonium gas are supplied to the semiconductor substrate 30 for about 20˜30 seconds, the rapid thermal nitridation process is carried out under the pressure of about 1˜2 Torr and at a temperature of about 700˜800° C. Since the polysilicon film 40 is deposited along the profile of the opening 38a formed in the second insulating layer 38, the supporting film 42 is formed on the inner surface and the bottom surface of the polysilicon film 40.

The polysilicon is typically crystallized at a temperature of about 540˜560° C. Therefore, the polysilicon film 40 is re-crystallized when the subsequent process is performed at a high temperature. A material having a thermal stability and a good deposition characteristic is coated on the inner surface of the polysilicon film 40 before the subsequent process is performed, so that a pair bit failure, such as the inclination of the storage node due to the re-crystallization of the polysilicon decreases.

The polysilicon film 40 is not inclined although the process of forming the supporting film 42 is carried out at a temperature of 700˜800° C. This is because as the polysilicon film 40 is deposited at the opening 38a formed in the second insulating layer 38, the outer surface of the polysilicon film 40 is completely supported by the second insulating layer 38.

FIG. 4E shows the step of forming a sacrificial layer 44 filling up the opening 38a in which the polysilicon film 40 and the support film 42 are formed.

FIG. 4F shows the step of forming the storage electrode 40a of a cylindrical shape in which the sacrificial layer 44 and second insulating layer 38 are substantially or completely removed after an upper portion of the sacrificial layer 44 is etched back so as to separate the polysilicon film 40 and the supporting film 42 into a node unit.

In particular, the upper portion of the sacrificial layer 44 is etched back by a chemical and mechanical polishing or a dry etching so that the polysilicon film 40 and the supporting film 42 remains only on the sidewall and the bottom surface of the opening 38a. Accordingly, since the polysilicon film 40 and the supporting film 42 which are deposited on the surface of the second insulating layer 38 are polished, the polysilicon film 40 and the supporting film 42 deposited along the profile of the opening 38a are respectively separated into a node unit. A distance between the nodes of the polysilicon film 40 separated by the etch back process is about 300˜1,000 Å.

Next, all or substantially all of the remaining sacrificial layer 44 and the second insulating layer 38 are removed to form the storage electrode 40a which is separated into a node unit. The removal of the sacrificial layer 44 and the second insulating layer 38 may be performed by a wet etching process. The storage electrode 40a which is separated into a node unit has a cylindrical shape in which an upper portion is wide and a lower portion is narrow, and has a height of about 10,000˜17,000 Å. The supporting film pattern 42a is formed on the inner surface and the bottom surface of the storage electrode 40a.

FIG. 4G shows the step of forming a capacitor of the semiconductor device in which a reaction barrier film 46, a dielectric film 48 and a plate film 50 are sequentially formed on the storage electrode 40a having the supporting film pattern 42a formed on the inner surface and the bottom surface thereof.

The dielectric film 48 may be comprised of a high dielectric material such as a tantalum oxide (Ta₂O₅) or an aluminum oxide (Al₂O₃). However, since the dielectric film 48 may be reacted with the silicon included in the storage electrode 40a when the dielectric film 48 is formed, the reaction barrier film 46 is preferably formed to keep the dielectric film 48 from reacting with the storage electrode 40a before the dielectric film 48 is formed.

A gas including a nitrogen source is provided to the semiconductor substrate 30 to nitrify the surface of the storage electrode 40a at a temperature of about 500˜1,000° C., resulting in forming the reaction barrier film 46. The dielectric film 48 is formed after the reaction barrier film 46 is formed. The capacitor of the semiconductor device is accomplished by depositing the conductive material on the dielectric film 48 to form the plate electrode 50.

The storage electrode 40a has an unstable geometric structure in which the upper portion thereof is wide and the lower portion thereof is narrow. Further, the distance between nodes of the storage electrodes 40a becomes narrower as the height of the storage electrode 40a increases. When the storage node is inclined or falls down due to the process failure, bridges occur between the nodes. Thereby, two unit cells having the nodes experience a function failure (pair bit failure).

The function failure of the unit cells frequently occurs when the subsequent process is performed after the storage electrode 40a is formed. The function failure of the unit cell is caused mainly after forming the reaction barrier film 46. because the process of forming the reaction barrier film 46 is performed at a high temperature, and the polysilicon of the storage electrode 40a is re-crystallized and thus silicon atoms of the storage electrode 40a are rearranged so that each of the nodes of the storage electrode 40a is inclined.

However, since the thermally stable supporting film pattern 42a is formed on the inner surface and the bottom surface of the storage electrode 40a, the inclination of the storage node can be reduced when the subsequent thermal process is carried out. Accordingly, a function failure due to the inclination of the storage node can be reduced.

According to the present invention, as the surface of the polysilicon film is nitrified to form the supporting film after forming the polysilicon to form the storage electrode, the inclination of the storage node can be redcued when the subsequent thermal process is performed. Therefore, the function failure of the two cells by the occurrence of bridges formed between the adjacent nodes due to the inclination of the storage node can be reduced. Accordingly, improvements in the reliability, the productivity, and the yield of the semiconductor device may be realized.

Although the preferred embodiments of the present invention have been described, it is understood that the present invention should not be limited to these preferred embodiments but various changes and modifications can be made by one skilled in the art within the spirit and scope of the present invention as hereinafter claimed.

What is claimed is:

1. A capacitor comprising:
a storage electrode of a polysilicon film which is continuously coated on a side wall and a bottom surface of an opening which partially exposes a conductive structure formed under said storage electrode, said opening being formed at a portion of an insulating layer formed on a semiconductor substrate and said insulating layer being removed after forming the storage electrode;
a supporting film pattern, formed on an inner surface and a bottom surface of the storage electrode, for supporting said storage electrode; and
a dielectric film and a plate electrode, which are subsequently formed on the storage electrode on which the supporting film pattern is formed.

2. A capacitor as claimed in claim 1, wherein the supporting film pattern is comprised of silicon nitride or silicon oxynitride.

3. A capacitor as claimed in claim 1, wherein the supporting film pattern has a thickness of about 5˜30 Å.

4. A method of manufacturing a capacitor comprising:
forming an opening at a portion of an insulating layer which is formed on a semiconductor substrate for exposing a conductive structure under the insulating layer;
forming a polysilicon film on the insulating layer, a side wall and a bottom surface of the opening;
forming a supporting film for supporting the polysilicon film on the polysilicon film;
forming a storage electrode of the polysilicon film on the side wall and the bottom surface of the opening by partially removing the polysilicon film and the supporting film which are formed on the insulating layer; and
forming a dielectric layer and a plate electrode on the storage electrode.

5. A method of manufacturing a capacitor as claimed in claim 4, wherein the supporting film pattern is comprised of silicon nitride or silicon oxynitride.

6. A method of manufacturing a capacitor as claimed in claim 4, wherein the supporting film pattern has a thickness of about 5˜30 Å.

7. A method of manufacturing a capacitor as claimed in claim 4, wherein the supporting film is formed by a rapid thermal nitridation process in which a surface of the polysilicon film is nitrated under a gas ambient including a nitrogen source.

8. A method of manufacturing a capacitor as claimed in claim 7, wherein the supporting film is formed by supplying silane gas and ammonium gas to the polysilicon film for about 20˜200 seconds under a pressure of about 1-2 Torr and at a temperature of about 700˜800° C.

9. A method of manufacturing a capacitor as claimed in claim 4, wherein the conductive structure is a contact plug which is formed to make contact with a portion of the semiconductor substrate and is comprised of a conductive material.

10. A method of manufacturing a capacitor as claimed in claim 9, further comprising forming an etching stop layer on the insulating layer.

11. A method of manufacturing a capacitor as claimed in claim 4, wherein the storage electrode has a height of about 10000˜18000 Å.

12. A method of manufacturing a capacitor as claimed in claim 4, wherein the storage electrode is formed by:
forming a sacrificial layer which fills up the opening in which the polysilicon film and the supporting film are formed on the side wall and the bottom surface of the opening;
etching back the sacrificial layer but leaving the polysilicon film and the supporting film only on the side wall and the bottom surface of the opening to thereby form the storage electrode into at least one node; and
removing the sacrificial layer and insulating layer.

13. A method of manufacturing a capacitor as claimed in claim 12, wherein said etching back is performed by polishing or dry etching process.

14. A method of manufacturing a capacitor as claimed in claim 12, wherein said etching back is performed so that a distance between the nodes is about 400˜1500 Å.

15. A method of manufacturing a capacitor as claimed in claim 4, further comprising forming a reaction barrier film on the storage electrode after said forming the storage electrode.

16. A method of manufacturing a capacitor as claimed in claim 10, wherein the reaction barrier film is formed at a temperature of 700˜800° C. under a gas ambient including a nitrogen source.

17. A capacitor comprising:
a storage electrode of a polysilicon film;
a supporting film pattern, formed on an inner surface and a bottom surface of the storage electrode, for supporting said storage electrode; and
a dielectric film and a plate electrode, which are subsequently formed on the storage electrode on which the supporting film pattern is formed.

18. A capacitor comprising:
a storage electrode of a polysilicon film;
a supporting film pattern, formed on an inner surface and a bottom surface of the storage electrode, for thermally supporting said storage electrode; and
a dielectric film and a plate electrode, which are subsequently formed on the storage electrode on which the supporting film pattern is formed.

19. A method of manufacturing a capacitor comprising:
forming an opening at a portion of an insulating layer which is formed on a semiconductor substrate for exposing a conductive structure under the insulating layer;
forming a polysilicon film on the insulating layer, a side wall and a bottom surface of the opening;
forming a supporting film for thermally supporting the polysilicon film on the polysilicon film;
forming a storage electrode of the polysilicon film on the side wall and the bottom surface of the opening by partially removing the polysilicon film and the supporting film which are formed on the insulating layer; and
forming a dielectric layer and a plate electrode on the storage electrode.
